(19) United States
(12) Patent Application Publication
(10) Pub. No.: US 2012/0033820 A1
(43) Pub. Date: Feb. 9, 2012

(54) AUDIO PLAYER

(75) Inventor: TAO WANG, Shenzhen City (CN)

(73) Assignees: HON HAI PRECISION INDUSTRY CO., LTD., Tu-Cheng (TW); HONG FU JIN PRECISION INDUSTRY(ShenZhen) CO., LTD., Shenzhen City (CN)

(21) Appl. No.: 13/156,427

(22) Filed: Jun. 9, 2011

(30) Foreign Application Priority Data
Aug. 4, 2010 (CN) 201010245018.X

(51) Int. Cl. H03G 11/00

(52) U.S. Cl. 381/55

(57) ABSTRACT

An audio player includes a reading unit, a processing unit, a speaker, and a protection unit. The reading unit acquires an audio file stored in a memory. The processing unit processes the acquired audio file to generate an audio signal. The speaker reproduces the audio signal. The protection unit is connected between the processing unit and the speaker and is used for detecting temperature changes of the speaker. An internal resistance of the protection unit is automatically adjusted according to temperature changes of the speaker to adjust the current of the audio signal flowing from the processing unit to the speaker.

### BACKGROUND

1. Technical Field

The disclosed embodiments relate to audio players.

2. Description of Related Art

An audio player, such as portable MP3 player, DVD player, etc. is used for playing audio files and outputting sound through a speaker. When the volume of the speaker is too high and the high volume is sustained for a long time, the temperature of the speaker may get too high, thus the speaker may be damaged, and further, some electronic components of the audio player may be damaged.

What is needed, therefore, is an audio player and an electronic device to overcome the above described limitations.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout one view.

The FIGURE is a circuit diagram of an audio player in accordance with one embodiment.

### DETAILED DESCRIPTION

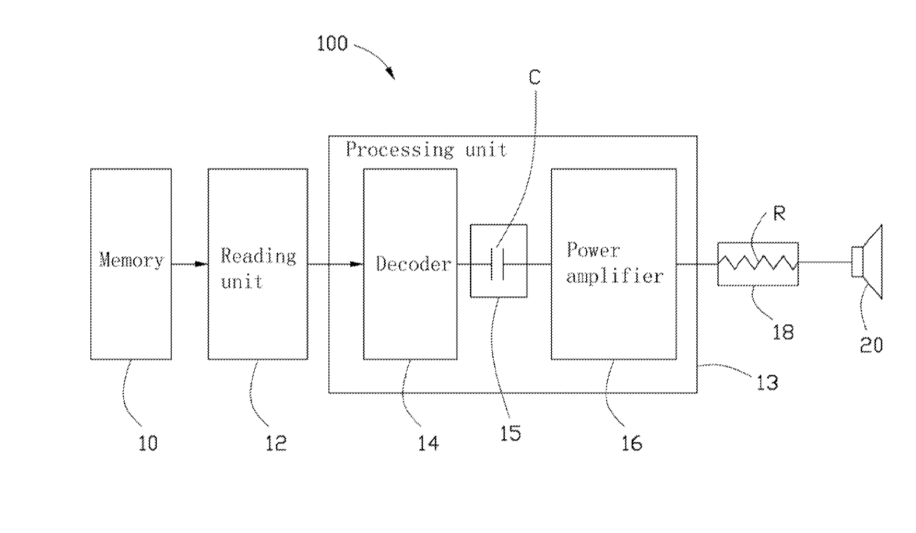

Referring to FIG. 1, an electronic device 100 includes a memory 10, a reading unit 12, a processing unit 13, a protection unit 18, and a speaker 20. The memory 10 stores a plurality of audio files. In this embodiment, the electronic device 100 is an audio player. In other embodiments, the memory 10 is an external storage medium and is not included in the audio player 100, such as an optical disc.

The reading unit 12 is used for acquiring an audio file stored in the memory 10. The processing unit 13 is used for processing the acquired audio file to generate an audio signal. In detail, the processing unit 13 includes a decoder 14, a coupling circuit 15, and a power amplifier 16. The decoder 14 decodes the acquired audio file to generate the audio signal. The power amplifier 16 amplifies the audio signal and provides the amplified audio signal to the speaker 16 through the protection unit 18. The coupling circuit 15 is used for filtering the DC portion of the audio signal transmitted from the decoder 14 to the power amplifier 16. In this embodiment, the coupling circuit 15 includes a coupling capacitor 15 connected between the decoder 14 and the power amplifier 16.

The speaker 20 is used for reproducing the amplified audio signal. The protection unit 18 is connected between the processing unit 13 and the speaker 20, and is used for detecting temperature changes of the speaker 20. An internal resistance of the protection unit 18 is automatically adjusted according to temperature changes of the speaker 20 to adjust a current of the audio signal flowing from the power amplifier 16 to the speaker 20. In detail, when the temperature of the speaker 20 increases, the internal resistance of the protection unit 18 also increases, therefore the current of the audio signal flowing from the power amplifier 16 to the speaker 20 decreases, and the temperature of the speaker 20 will decrease. Therefore, the damage of the speaker 20 is effectively prevented.

Furthermore, when the temperature of the speaker 20 decreases, the internal resistance of the protection unit 18 also decreases, therefore the electric energy consumed by the protection unit 18 is reduced, the power efficiency of the audio player 100 is enhanced. In detail, the protection unit 18 includes a thermal resistor R, the thermal resistor R is connected in series between the power amplifier 16 and the speaker 20. When the temperature of the speaker 20 is increased, the resistance of the thermal resistor R is also increased. When the temperature of the speaker 20 is decreased, the resistance of the thermal resistor R is also decreased.

Alternative embodiments will become apparent to those skilled in the art without departing from the spirit and scope of what is claimed. Accordingly, the present invention should be deemed not to be limited to the above detailed description, but rather only by the claims that follow and equivalents thereof.

What is claimed is:

1. An audio player, comprising:
a reading unit for acquiring an audio file stored in a memory;
a processing unit for processing the acquired audio file to generate an audio signal;
a speaker for reproducing the audio signal; and
a protection unit connected between the processing unit and the speaker for detecting temperature changes of the speaker;
wherein an internal resistance of the protection unit is automatically adjusted according to temperature changes of the speaker to adjust a current of the audio signal flowing from the processing unit to the speaker.

2. The audio player of claim 1, wherein the protection unit comprises a thermal resistor, the thermal resistor is connected in series between the processing unit and the speaker.

3. The audio player of claim 2, wherein the thermal resistor is a positive temperature coefficient thermal resistor, the resistance of the thermal resistor is increased with the increased temperature of the speaker.

4. The audio player of claim 1, wherein the processing unit comprises a decoder for decoding the acquired audio file to generate the audio signal.

5. The audio player of claim 4, wherein the processing unit further comprises a power amplifier for amplifying the audio signal and providing the amplified audio signal to the speaker through the protection unit.

6. The audio player of claim 5, wherein the processing unit comprises a coupling circuit for filtering the DC portion of the audio signal transmitted from the decoder to the power amplifier.

7. The audio player of claim 6, wherein the coupling circuit comprises a coupling capacitor connected between the decoder and the power amplifier.

8. The audio player of claim 1, wherein the audio player comprises the memory for storing a plurality of audio files.

9. An audio player, comprising:
a processing unit for providing an audio signal;
a speaker for reproducing the audio signal; and
a protection unit connected between the processing unit and the speaker for adjusting a current of the audio signal flowing from the processing unit to the speaker;
wherein the protection unit is further used for detecting temperature of the speaker, an internal resistance of the protection unit is increased when the temperature of the speaker is increased and is decreased when the temperature of the speaker is decreased.

10. The audio player of claim 9, wherein the protection unit comprises a thermal resistor, the thermal resistor is connected in series between the processing unit and the speaker.

11. The audio player of claim 10, wherein the thermal resistor is a positive temperature coefficient thermal resistor, the resistance of the thermal resistor is increased with the increased temperature of the speaker.

12. The audio player of claim 9, wherein the processing unit comprises a decoder for decoding the acquired audio file to generate the audio signal.

13. The audio player of claim 12, wherein the processing unit further comprises a power amplifier for amplifying the audio signal and providing the amplified audio signal to the speaker through the protection unit.

14. The audio player of claim 13, wherein the processing unit comprises a coupling circuit for filtering the DC portion of the audio signal transmitted from the decoder to the power amplifier.

15. The audio player of claim 14, wherein the coupling circuit comprises a coupling capacitor connected between the decoder and the power amplifier.

16. The audio player of claim 9, further comprising a reading unit for acquiring an audio file stored in a memory, wherein the processing unit is used for processing the acquired audio file to generate the audio signal.

17. The audio player of claim 16, further comprising the memory for storing a plurality of audio files.
